(19) United States
(12) Patent Application Publication
(10) Pub. No.: US 2025/0357662 A1
(43) Pub. Date: Nov. 20, 2025

(54) ELECTRICALLY SMALL AND LOW PROFILE FM ANTENNA

(71) Applicant: GM Global Technology Operations LLC, Detroit, MI (US)

(72) Inventors: Duane S. Carper, Davison, MI (US); Gregg R. Kittinger, Oakland Twp., MI (US); Patrick Edward Leavy, Akron, MI (US); Hanseung Lee, Thousand Oaks, CA (US); Daniel Kuzmenko, Roseville, CA (US); Hyok Jae Song, Oak Park, CA (US)

(73) Assignee: GM Global Technology Operations LLC, Detroit, MI (US)

(21) Appl. No.: 18/667,555

(22) Filed: May 17, 2024

(51) Int. Cl. H01Q 1/32; H01Q 9/42; H03F 3/19

(52) U.S. Cl. CPC H01Q 1/3291; H01Q 9/42; H03F 3/19

(57) ABSTRACT

A radio antenna includes a folded monopole radiator, a high impedance buffer amplifier, and a grounding cable. The amplifier includes an input side, an output side, a two-pole filter, and a voltage regulator. The input side is electrically connected to the folded monopole radiator and maintains a consistent level of impedance, while the output side is electrically connected to a power source and maintains a consistent level of impedance. The two-pole filter attenuates frequencies, and the voltage regulator is configured to supply the buffer amplifier with a fixed DC bias voltage when power is received from the power source. The flexible grounding cable is directly wired to the amplifier, includes a metallic mounting end, and is positioned to maintain the consistent level of impedance at the folded monopole radiator.

### INTRODUCTION

The information provided in this section is for the purpose of generally presenting the context of the disclosure. Work of the presently named inventors, to the extent it is described in this section, as well as aspects of the description that may not otherwise qualify as prior art at the time of filing, are neither expressly nor impliedly admitted as prior art against the present disclosure.

The present disclosure relates generally to an FM radio antenna for use in a vehicle. FM radio broadcast frequency is between about 76 MHz and 108 MHz, which has a wavelength of about three to four meters. To accommodate sufficient and static-free reception of this wavelength, FM radio antennas have historically been configured to be one quarter of its wavelength, or about three quarters of one meter to one meter. This length requirement for FM radio antennas has created limitations in terms of antenna placement on vehicles. In many circumstances, the FM radio antenna has been incorporated onto a glass panel disposed at the vehicle. However, this configuration of FM radio antenna demands that each different vehicle model has a different FM radio antenna to accommodate the glass panels and overall design of each specific vehicle. Furthermore, as FM radio antennas require a level of impedance at or near 50 ohms to function properly, the design differences in each vehicle model prevent a universal application of the FM radio antenna. In other applications, FM radio antennas have been included in a roof-mounted “sharkfin” antenna module, however, if the roof of a vehicle is not comprised of metal and is, alternatively, comprised solely of glass, proper grounding of the FM radio antenna to a metallic surface cannot be accommodated. Additionally, the aesthetic of the “sharkfin” antenna may not always be desirable in certain vehicle applications. There is a desire for a compact FM radio antenna that may be entirely concealed within a vehicle application, universally adapted to multiple vehicle models without reconfiguration, while still maintaining clear and static-free reception of the FM radio band.

### SUMMARY

One aspect of the disclosure provides a radio antenna. The radio antenna includes a folded monopole radiator, a high impedance buffer amplifier, and a flexible grounding cable. The buffer amplifier includes an input side, an output side, a two-pole filter, and a voltage regulator. The input side is electrically connected to the folded monopole radiator and maintains a consistent level of impedance, while the output side is electrically connected to a power source and maintains the consistent level of impedance. The two-pole filter attenuates frequencies, and the voltage regulator is configured to supply the buffer amplifier with a fixed DC bias voltage when power is received from the power source. The flexible grounding cable is directly wired to the buffer amplifier and includes a metallic mounting end. The flexible grounding cable is positioned to maintain the consistent level of impedance at the folded monopole radiator.

Implementations of the disclosure may include one or more of the following optional features. In some examples, the buffer amplifier and the grounding cable are configured to maintain an output impedance at 50 ohms, the output impedance received by the monopole radiator.

In some implementations, the monopole radiator includes a metallic material and may include a horizontal portion and a vertical portion. In some further implementations, the vertical portion includes a lower end fixed to the buffer amplifier, and an upper end fixed to the horizontal portion.

In some aspects, the monopole radiator is configured to capture signals in the FM radio band.

In some examples, the radio antenna is disposed at a vehicle. In some further examples, the metallic mounting end of the grounding cable is fixed to a metallic mounting surface of the vehicle. In some other further examples, the radio antenna is disposed behind a body component of the vehicle.

Another aspect of the disclosure provides a body component for a vehicle. The body component includes a radio antenna disposed at the body component. The radio antenna includes a folded monopole radiator, a high impedance buffer amplifier, and a flexible grounding cable. The buffer amplifier includes an input side, an output side, a two-pole filter, and a voltage regulator. The input side is electrically connected to the folded monopole radiator and maintains a consistent level of impedance, while the output side is electrically connected to a power source and maintains the consistent level of impedance. The two-pole filter attenuates frequencies, and the voltage regulator is configured to supply the buffer amplifier with a fixed DC bias voltage when power is received from the power source. The flexible grounding cable is directly wired to the buffer amplifier and includes a metallic mounting end. The flexible grounding cable is positioned to maintain the consistent level of impedance at the folded monopole radiator.

Implementations of this aspect of the disclosure may include one or more of the following optional features. In some examples, the buffer amplifier and the grounding cable are configured to maintain an output impedance at 50 ohms, the output impedance received by the monopole radiator.

In some implementations, the monopole radiator includes a metallic material and may include a horizontal portion and a vertical portion. In some further examples, the vertical portion includes a lower end fixed to the buffer amplifier, and an upper end fixed to the horizontal portion.

In some aspects, the monopole radiator is configured to capture signals in the FM radio band.

In some examples, the body component is installed at the vehicle. In some further examples, the metallic mounting end of the grounding cable is fixed to a metallic mounting surface of the vehicle.

Yet another aspect of the disclosure provides a vehicle. The vehicle includes a body component and a radio antenna disposed behind the body component. The radio antenna includes a folded monopole radiator, a high impedance buffer amplifier, and a flexible grounding cable. The buffer amplifier includes an input side, an output side, a two-pole filter, and a voltage regulator. The input side is electrically connected to the folded monopole radiator and maintains a consistent level of impedance, while the output side is electrically connected to a power source and maintains the consistent level of impedance. The two-pole filter attenuates frequencies, and the voltage regulator is configured to supply the buffer amplifier with a fixed DC bias voltage when power is received from the power source. The flexible grounding cable is directly wired to the buffer amplifier and includes a metallic mounting end. The flexible grounding cable is positioned to maintain the consistent level of impedance at the folded monopole radiator.

Implementations of this aspect of the disclosure may include one or more of the following optional features. In some examples, the buffer amplifier and the grounding cable are configured to maintain an output impedance at 50 ohms, the output impedance received by the monopole radiator.

In some implementations, the monopole radiator includes a metallic material and may include a horizontal portion and a vertical portion, the vertical portion including a lower end fixed to the buffer amplifier and an upper end fixed to the horizontal portion.

In some aspects, the monopole radiator is configured to capture signals in the FM radio band.

In some examples, the metallic mounting end of the grounding cable is fixed to a metallic mounting surface of the vehicle.

### BRIEF DESCRIPTION OF THE DRAWINGS

The drawings described herein are for illustrative purposes only of selected configurations and are not intended to limit the scope of the present disclosure.

FIG. 1 is a perspective view of a vehicle that includes a low profile active FM radio antenna.

FIG. 2 is a perspective view of the low profile active FM radio antenna.

FIG. 3 is a top-side view of a high impedance buffer amplifier of the low profile active FM radio antenna

FIG. 4 is a circuit diagram of the high impedance buffer amplifier of FIG. 3.

FIG. 5 is a top-side view of the vehicle of FIG. 1, indicating example positions on the vehicle for mounting the low profile active FM radio antenna.

FIG. 6 is a compilation of four far field pattern charts of the low profile active FM radio antenna from the example positions of FIG. 5, where each chart indicates a different FM frequency.

Corresponding reference numerals indicate corresponding parts throughout the drawings.

### DETAILED DESCRIPTION

Example configurations will now be described more fully with reference to the accompanying drawings. Example configurations are provided so that this disclosure will be thorough, and will fully convey the scope of the disclosure to those of ordinary skill in the art. Specific details are set forth such as examples of specific components, devices, and methods, to provide a thorough understanding of configurations of the present disclosure. It will be apparent to those of ordinary skill in the art that specific details need not be employed, that example configurations may be embodied in many different forms, and that the specific details and the example configurations should not be construed to limit the scope of the disclosure.

The terminology used herein is for the purpose of describing particular exemplary configurations only and is not intended to be limiting. As used herein, the singular articles “a,” “an,” and “the” may be intended to include the plural forms as well, unless the context clearly indicates otherwise. The terms “comprises,” “comprising,” “including,” and “having,” are inclusive and therefore specify the presence of features, steps, operations, elements, and/or components, but do not preclude the presence or addition of one or more other features, steps, operations, elements, components, and/or groups thereof. The method steps, processes, and operations described herein are not to be construed as necessarily requiring their performance in the particular order discussed or illustrated, unless specifically identified as an order of performance. Additional or alternative steps may be employed.

When an element or layer is referred to as being “on,” “engaged to,” “connected to,” “attached to,” or “coupled to” another element or layer, it may be directly on, engaged, connected, attached, or coupled to the other element or layer, or intervening elements or layers may be present. In contrast, when an element is referred to as being “directly on,” “directly engaged to,” “directly connected to,” “directly attached to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

The terms “first,” “second,” “third,” etc. may be used herein to describe various elements, components, regions, layers and/or sections. These elements, components, regions, layers and/or sections should not be limited by these terms. These terms may be only used to distinguish one element, component, region, layer or section from another region, layer or section. Terms such as “first,” “second,” and other numerical terms do not imply a sequence or order unless clearly indicated by the context. Thus, a first element, component, region, layer or section discussed below could be termed a second element, component, region, layer or section without departing from the teachings of the example configurations.

In this application, including the definitions below, the term “module” may be replaced with the term “circuit.” The term “module” may refer to, be part of, or include an Application Specific Integrated Circuit (ASIC); a digital, analog, or mixed analog/digital discrete circuit; a digital, analog, or mixed analog/digital integrated circuit; a combinational logic circuit; a field programmable gate array (FPGA); a processor (shared, dedicated, or group) that executes code; memory (shared, dedicated, or group) that stores code executed by a processor; other suitable hardware components that provide the described functionality; or a combination of some or all of the above, such as in a system-on-chip.

The term “code,” as used above, may include software, firmware, and/or microcode, and may refer to programs, routines, functions, classes, and/or objects. The term “shared processor” encompasses a single processor that executes some or all code from multiple modules. The term “group processor” encompasses a processor that, in combination with additional processors, executes some or all code from one or more modules. The term “shared memory” encompasses a single memory that stores some or all code from multiple modules. The term “group memory” encompasses a memory that, in combination with additional memories, stores some or all code from one or more modules. The term “memory” may be a subset of the term “computer-readable medium.” The term “computer-readable medium” does not encompass transitory electrical and electromagnetic signals propagating through a medium, and may therefore be considered tangible and non-transitory memory. Non-limiting examples of a non-transitory memory include a tangible computer readable medium including a nonvolatile memory, magnetic storage, and optical storage.

The apparatuses and methods described in this application may be partially or fully implemented by one or more computer programs executed by one or more processors. The computer programs include processor-executable instructions that are stored on at least one non-transitory tangible computer readable medium. The computer programs may also include and/or rely on stored data.

A software application (i.e., a software resource) may refer to computer software that causes a computing device to perform a task. In some examples, a software application may be referred to as an “application,” an “app,” or a “program.” Example applications include, but are not limited to, system diagnostic applications, system management applications, system maintenance applications, word processing applications, spreadsheet applications, messaging applications, media streaming applications, social networking applications, and gaming applications.

The non-transitory memory may be physical devices used to store programs (e.g., sequences of instructions) or data (e.g., program state information) on a temporary or permanent basis for use by a computing device. The non-transitory memory may be volatile and/or non-volatile addressable semiconductor memory. Examples of non-volatile memory include, but are not limited to, flash memory and read-only memory (ROM)/programmable read-only memory (PROM)/erasable programmable read-only memory (EPROM)/electronically erasable programmable read-only memory (EEPROM) (e.g., typically used for firmware, such as boot programs). Examples of volatile memory include, but are not limited to, random access memory (RAM), dynamic random access memory (DRAM), static random access memory (SRAM), phase change memory (PCM) as well as disks or tapes.

These computer programs (also known as programs, software, software applications or code) include machine instructions for a programmable processor, and can be implemented in a high-level procedural and/or object-oriented programming language, and/or in assembly/machine language. As used herein, the terms “machine-readable medium” and “computer-readable medium” refer to any computer program product, non-transitory computer readable medium, apparatus and/or device (e.g., magnetic discs, optical disks, memory, Programmable Logic Devices (PLDs)) used to provide machine instructions and/or data to a programmable processor, including a machine-readable medium that receives machine instructions as a machine-readable signal. The term “machine-readable signal” refers to any signal used to provide machine instructions and/or data to a programmable processor.

Various implementations of the systems and techniques described herein can be realized in digital electronic and/or optical circuitry, integrated circuitry, specially designed ASICs (application specific integrated circuits), computer hardware, firmware, software, and/or combinations thereof. These various implementations can include implementation in one or more computer programs that are executable and/or interpretable on a programmable system including at least one programmable processor, which may be special or general purpose, coupled to receive data and instructions from, and to transmit data and instructions to, a storage system, at least one input device, and at least one output device.

The processes and logic flows described in this specification can be performed by one or more programmable processors, also referred to as data processing hardware, executing one or more computer programs to perform functions by operating on input data and generating output. The processes and logic flows can also be performed by special purpose logic circuitry, e.g., an FPGA (field programmable gate array) or an ASIC (application specific integrated circuit). Processors suitable for the execution of a computer program include, by way of example, both general and special purpose microprocessors, and any one or more processors of any kind of digital computer. Generally, a processor will receive instructions and data from a read only memory or a random access memory or both. The essential elements of a computer are a processor for performing instructions and one or more memory devices for storing instructions and data. Generally, a computer will also include, or be operatively coupled to receive data from or transfer data to, or both, one or more mass storage devices for storing data, e.g., magnetic, magneto optical disks, or optical disks. However, a computer need not have such devices. Computer readable media suitable for storing computer program instructions and data include all forms of non-volatile memory, media and memory devices, including by way of example semiconductor memory devices, e.g., EPROM, EEPROM, and flash memory devices; magnetic disks, e.g., internal hard disks or removable disks; magneto optical disks; and CD ROM and DVD-ROM disks. The processor and the memory can be supplemented by, or incorporated in, special purpose logic circuitry.

To provide for interaction with a user, one or more aspects of the disclosure can be implemented on a computer having a display device, e.g., a CRT (cathode ray tube), LCD (liquid crystal display) monitor, or touch screen for displaying information to the user and optionally a keyboard and a pointing device, e.g., a mouse or a trackball, by which the user can provide input to the computer. Other kinds of devices can be used to provide interaction with a user as well; for example, feedback provided to the user can be any form of sensory feedback, e.g., visual feedback, auditory feedback, or tactile feedback; and input from the user can be received in any form, including acoustic, speech, or tactile input. In addition, a computer can interact with a user by sending documents to and receiving documents from a device that is used by the user; for example, by sending web pages to a web browser on a user's client device in response to requests received from the web browser.

An electrically small and low profile FM radio antenna for a vehicle includes a folded monopole radiator that is electrically connected to a high impedance buffer amplifier. As the small size of the radiator creates a high level of impedance, which can prevent clear reception of the FM radio band, the amplifier includes a voltage regulator and a flexible grounding cable that not only maintains a fixed DC bias voltage, regardless of the voltage of the vehicle's radio power supply, but also facilitates impedance transformation to maintain a level of impedance at the radiator to allow for clear reception of the FM radio band, even when the antenna is concealed by a non-conductor body part of the vehicle. Additionally, the grounding cable provides a significant amount of flexibility to place the radio antenna at a variety of locations in the vehicle without hampering the reception capabilities of the radiator. This configuration of the radio antenna is also universally acceptable into a variety of different vehicles and does not require modification of the radio antenna when installed in different vehicles, as the voltage and impedance of the radio antenna will always remain consistent regardless of its placement.

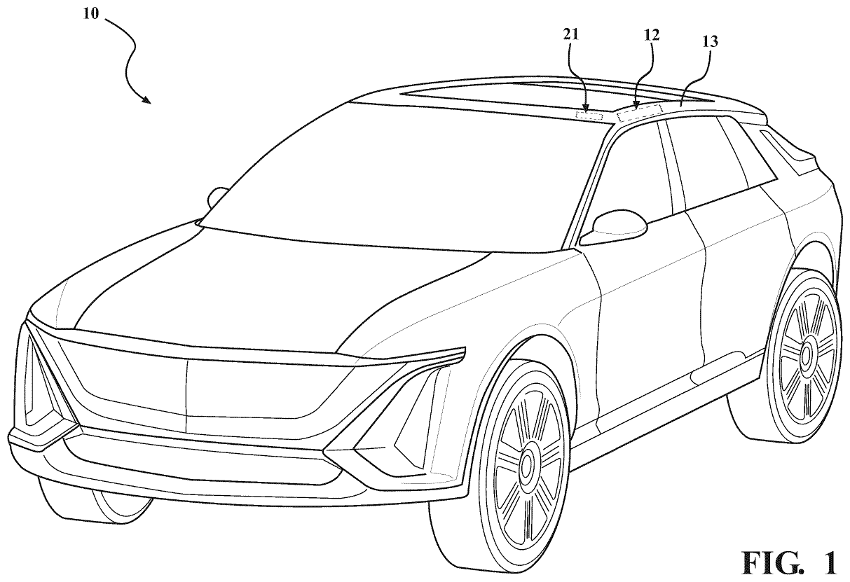

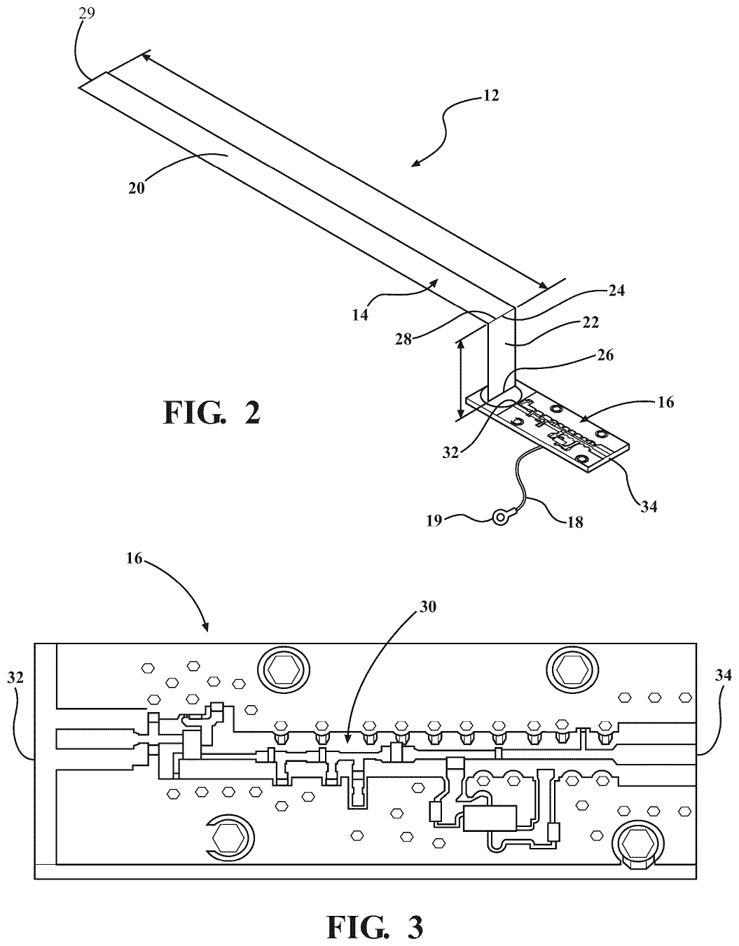

With reference to FIGS. 1-3, a vehicle 10 includes an active FM radio antenna 12 concealed or at partially concealed by a vehicle body panel or body part 13. The radio antenna 12 includes a folded monopole radiator 14, a high impedance buffer amplifier 16, and a grounding cable 18. The radiator 14 includes a horizontal portion 20 and a vertical portion 22, the vertical portion 22 including an upper end 24 and a lower end 26. The lower end 26 is attached at the high impedance buffer amplifier 16 and the upper end 24 is distal to the high impedance buffer amplifier 16. The horizontal portion 20 includes an inner end 28 at the upper end 24 of the vertical portion 22 and an outer end 29 distal to the upper end 24. The upper end 24 of the vertical portion 22 connects with the inner end 28 of the horizontal portion 20. The radiator 14 is formed of a metallic material and is configured to receive FM radio frequencies, the configuration of which is specifically sized to accommodate the reception of the frequencies within the FM radio band. In this example, the radiator 14 includes a height H22 of the vertical portion 22 that is 2.5 centimeters and includes a length L20 of the horizontal portion 20 that is 15 centimeters. However, it should be appreciated that the height of the vertical portion and the length of the horizontal portion may vary without deviating from the disclosure, as the ratio between the height of the vertical portion and the length of the horizontal portion achieves reception of the FM radio band. This example discloses a ratio of the height H22 of the vertical portion 22 to the length L20 of the horizontal portion 20 as 8.8. If it is desired to achieve frequencies outside of the FM radio band, the length-to-height ratio of the radiator may be adjusted.

The radiator 14 is electrically small and low profile. By describing the radiator 14 as electrically small, the radiator 14, isolated from the rest of the elements comprised in the FM radio antenna 12, has a short wavelength that does not by itself allow for clear and static-free reception of the FM radio band. Furthermore, by describing the radiator 14 as low profile, the vertical portion 22 of the radiator 14 is relatively small compared to traditional radiators and antennas. Because the radiator 14 is low profile, the potential locations of its placement within the vehicle 10 are vast, as its low profile size will accommodate its installation at multiple locations where a larger antenna would not fit due to space constraints of the vehicle 10.

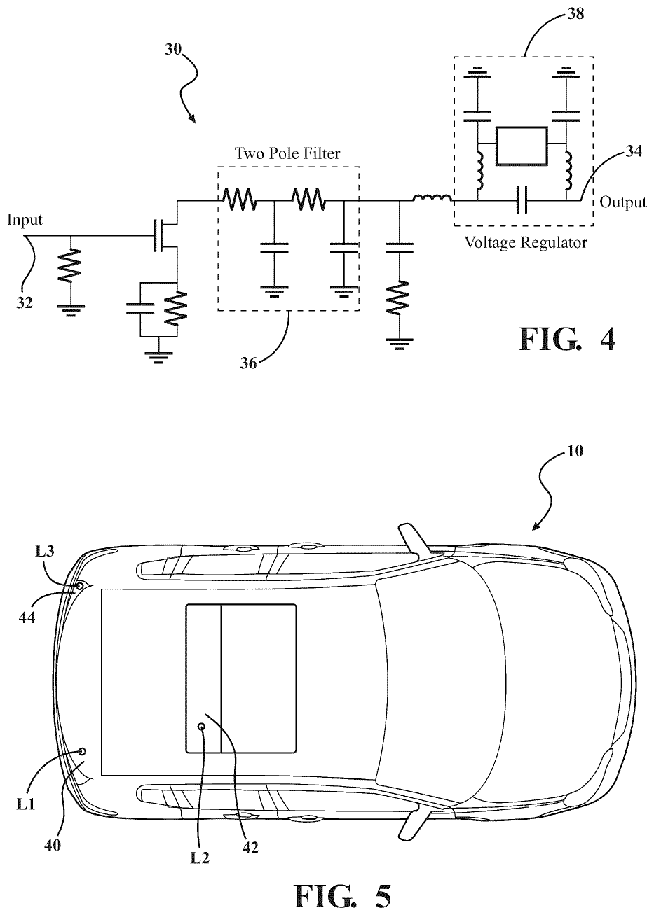

The amplifier 16 includes an electrical circuit 30 that comprises an input 32 and an output 34. The electrical circuit 30 maintains consistent levels of impedances at both an input 32 and an output 34. Electrically connected to the input 32 is the lower end 26 of the vertical portion 22 of the radiator 14. The output 34 is electrically connected to a power source, such as a receiver or powered radio disposed at the vehicle 10. With continued reference to FIGS. 1-3, and now with reference to FIG. 4, the electrical circuit 30 of the amplifier 16 includes a two-pole filter 36 and a voltage regulator 38. The two-pole filter 36 is configured to attenuate high frequencies, thereby enhancing stability of the radio system. The voltage regulator 38 is configured to supply the electrical circuit 30 with a fixed DC bias voltage when power is received from the power source. While the power source may provide varying or inconsistent levels of voltage to the amplifier 16, which may hamper performance of the FM radio antenna 12, the voltage regulator 38 prevents the electrical circuit 30 from experiencing voltage fluctuations.

Also included in the FM radio antenna 12 is a grounding cable 18 that is attached to the amplifier 16. The grounding cable 18 facilitates a means to ground the electrical circuit 30. The grounding cable 18 is flexible, providing variability in its placement in relation to the amplifier 16 and the radiator 14. A metallic mounting end 19 is included with the grounding cable 18 that provides a point of attachment of the grounding cable 18 to a metallic component or surface 21 disposed at the vehicle 10. With a grounding cable 18 that is flexible, its versatility allows the potential for the radiator 14 and amplifier 16 to be installed at a location that does not comprise a metallic surface. As long as the metallic mounting end 19 is fixed to the metallic surface 21 of the vehicle 10, the radiator 14 and the amplifier 16 may be installed at any location that can accommodate its compact size without degradation of FM radio reception.

Variations in placement of the FM radio antenna 12 at the vehicle 10, including variations in one or multiple body panels 13 that may conceal the FM radio antenna 12, variations in the material composition of body panels at or near the FM radio antenna 12, as well as the low profile size of the radiator 14, may impact impedance of the radiator 14 without voltage regulation, proper grounding, and impedance transformation. The amplifier 16 accommodates impedance transformation at the radiator 14, maintaining a consistent level of impedance despite the compact side of the radiator 14 and despite the mounting location of the FM radio antenna 12. In this example, impedance is maintained at or near 50 ohms, however, it should be appreciated that the level of impedance may differ without departing from the scope of this disclosure. As described, the amplifier 16, combined with proper grounding at the metallic mounting end 19 of the grounding cable 18, maintains a consistent level of impedance to allow the radiator 14 to sufficiently and clearly receive the FM radio band. Accordingly, the placement of the FM radio antenna 12 does not impact the impedance and, thus, will not affect the quality of FM radio band reception.

The mounting location of the FM radio antenna 12 is not universal amongst vehicles due to design variations in vehicle models as well as variations in body panels of individual vehicles. However, the impedance transformation and voltage regulation with proper grounding of the electrical circuit 30 facilitates placement at varying locations at the vehicle 10, or any vehicle, without modifying the FM radio antenna 12. In doing so, the proper voltage and impedance is always maintained, allowing the FM radio antenna 12 to function properly and provide clear reception of the FM radio band.

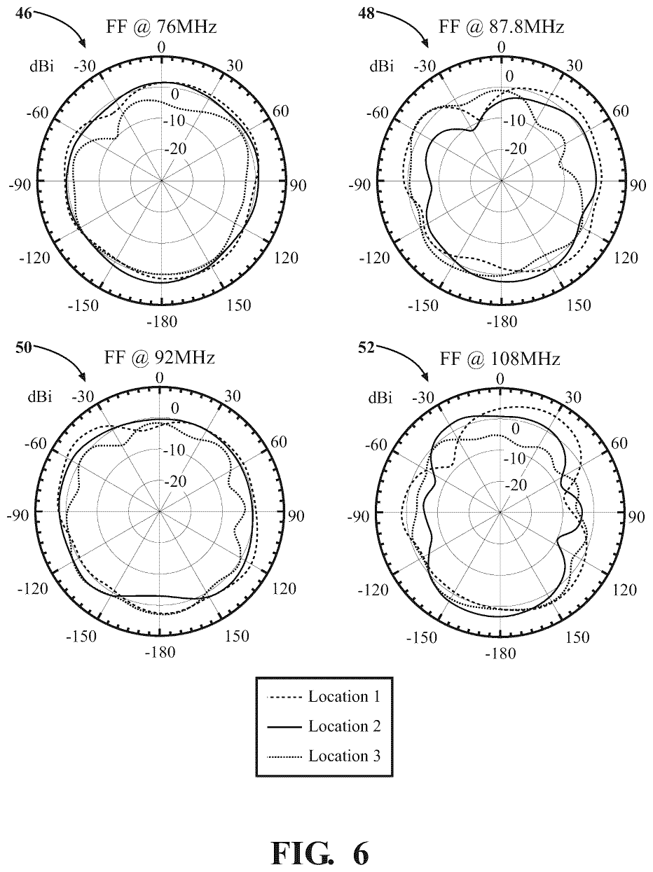

The experimental performance of the FM radio antenna 12 at various locations of the vehicle 10 (FIG. 5) are shown in FIG. 6. To accurately measure performance of the FM radio antenna 12, antenna gain-to-noise temperature (G/T, db/K) was measured at each of the locations using two frequencies at extreme ends of the FM radio band spectrum. Additionally, the far field patterns were recorded across using decibels relative to isotropic (dBi) at each of the locations using four different frequencies within the FM radio band to determine whether directional strength of the FM radio antenna 12 is consistent regardless of direction. The performance of the FM radio antenna 12 at each of the mounting locations shown in FIG. 5 is compared via a series of experiments or trials to determine whether different mounting locations will affect its performance.

The first experiment placed the FM radio antenna 12 at a first location L1 concealed by a spoiler 40 body component of the vehicle 10. That is, the antenna 12 is disposed at the vehicle 10 behind a spoiler 40 of the vehicle 10, which may be formed from a non-metallic material such as plastic. With the grounding cable 18 securely attached to a metallic mounting surface at or near the spoiler 40, and power sent to the FM radio antenna 12 from the vehicle 10, the antenna experienced a gain-to-noise temperature of −49.9 db/K at 70 MHz, and a gain-to-noise temperature of −44.4 db/K at 110 MHz. Additionally, a 76 MHz far field pattern 46 was recorded at the first location L1, as well as an 87.8 MHz far field pattern 48, a 92 MHz far field pattern 50, and a 108 MHz far field pattern 52, all of which occurred at the first location L1. All four far field patterns 46, 48, 50, 52 indicated strong and consistent directional power of the FM radio antenna 12 at the first location L1 across all directions.

The second experiment placed the FM radio antenna 12 at a second location L2 concealed by a roof glass 42 body component of the vehicle 10. That is, the antenna 12 is disposed at the vehicle 10 on or behind the glass panel 42 of the vehicle 10. With the grounding cable 18 securely attached to a metallic mounting surface at or near the roof glass 42, and power sent to the FM radio antenna 12 from the vehicle 10, the antenna experienced a gain-to-noise temperature of −51.0 db/K at 70 MHz, and a gain-to-noise temperature of −43.5 db/K at 110 MHz. Additionally, the 76 MHz far field pattern 46 was recorded at the second location L2, as well as an 87.8 MHz far field pattern 48, a 92 MHz far field pattern 50, and a 108 MHz far field pattern 52, all of which occurred at the second location L2. All four far field patterns 46, 48, 50, 52 indicated strong and consistent directional power of the FM radio antenna 12 at the second location L2 across all directions.

Finally, the third experiment placed the FM radio antenna 12 at a third location L3 concealed by a trunk door 44 body component of the vehicle 10, where the trunk door 44 may be formed from a non-metallic material. With the grounding cable 18 securely attached to a metallic mounting surface at or near the trunk door 44, and power sent to the FM radio antenna 12 from the vehicle 10, the antenna experienced a gain-to-noise temperature of −46.6 db/K at 70 MHz, and a gain-to-noise temperature of −41.4 db/K at 110 MHz. Additionally, the 76 MHz far field pattern 46 was recorded at the third location L3, as well as an 87.8 MHz far field pattern 48, a 92 MHz far field pattern 50, and a 108 MHz far field pattern 52, all of which occurred at the third location L3. All four far field patterns 46, 48, 50, 52 indicated strong and consistent directional power of the FM radio antenna 12 at the third location L3 across all directions.

Analyzing the results of all three experiments, performance of the FM radio antenna 12 is consistently strong regardless of its placement at the vehicle 10. Furthermore, the FM radio antenna 12 positioned in a manner where it is concealed by each body part 40, 42, 44 also does not degrade its performance. This allows the FM radio antenna 12 to be placed anywhere at the vehicle 10 without hampering its performance and clarity, and also allows the FM radio antenna 12 to be entirely concealed. As such, the overall aesthetics and styling of the vehicle 10 are improved.

A number of implementations have been described. Nevertheless, it will be understood that various modifications may be made without departing from the spirit and scope of the disclosure. Accordingly, other implementations are within the scope of the following claims.

The foregoing description has been provided for purposes of illustration and description. It is not intended to be exhaustive or to limit the disclosure. Individual elements or features of a particular configuration are generally not limited to that particular configuration, but, where applicable, are interchangeable and can be used in a selected configuration, even if not specifically shown or described. The same may also be varied in many ways. Such variations are not to be regarded as a departure from the disclosure, and all such modifications are intended to be included within the scope of the disclosure.

What is claimed is:

1. A radio antenna comprising:
a folded monopole radiator;
a high impedance buffer amplifier comprising:
an input side electrically connected to the folded monopole radiator and configured to maintain a consistent level of impedance,
an output side electrically connected to a power source and configured to maintain the consistent level of impedance,
a two-pole filter that attenuates frequencies, and
a voltage regulator configured to supply the buffer amplifier with a fixed (direct current) DC bias voltage when power is received from the power source; and
a flexible grounding cable directly wired to the amplifier and including a metallic mounting end, the flexible grounding cable positioned to maintain the consistent level of impedance at the folded monopole radiator.

2. The radio antenna of claim 1, wherein the buffer amplifier and the grounding cable are configured to maintain an output impedance at 50 ohms, the output impedance received by the monopole radiator.

3. The radio antenna of claim 1, wherein the monopole radiator comprises a metallic material, and wherein the monopole radiator comprises a horizontal portion and a vertical portion.

4. The radio antenna of claim 3, wherein the vertical portion comprises a lower end fixed to the buffer amplifier, and an upper end fixed to the horizontal portion.

5. The radio antenna of claim 1, wherein the monopole radiator is configured to capture signals in the FM radio band.

6. The radio antenna of claim 1, wherein the radio antenna is disposed at a vehicle.

7. The radio antenna of claim 6, wherein the metallic mounting end of the grounding cable is fixed to a metallic mounting surface of the vehicle.

8. The radio antenna of claim 6, wherein the radio antenna is disposed behind a body component of the vehicle.

9. A body component for a vehicle, the body component comprising:
a radio antenna disposed at the body component, the radio antenna comprising:
a folded monopole radiator,
a high impedance buffer amplifier comprising:
an input side electrically connected to the folded monopole radiator and configured to maintain a consistent level of impedance,
an output side electrically connected to a power source and configured to maintain the consistent level of impedance,
a two-pole filter that attenuates frequencies, and
a voltage regulator configured to supply the buffer amplifier with a fixed DC bias voltage when power is received from the power source, and
a flexible grounding cable directly wired to the amplifier and including a metallic mounting end, the flexible grounding cable positioned to maintain the consistent level of impedance at the folded monopole radiator.

10. The body component of claim 9, wherein the buffer amplifier and the grounding cable are configured to maintain an output impedance at 50 ohms, the output impedance received by the monopole radiator.

11. The body component of claim 9, wherein the monopole radiator comprises a metallic material, and wherein the monopole radiator comprises a horizontal portion and a vertical portion.

12. The body component of claim 11, wherein the vertical portion comprises a lower end fixed to the buffer amplifier, and an upper end fixed to the horizontal portion.

13. The body component of claim 9, wherein the monopole radiator is configured to capture signals in the FM radio band.

14. The body component of claim 9, wherein the body component is installed at the vehicle.

15. The body component of claim 14, wherein the metallic mounting end of the grounding cable is fixed to a metallic mounting surface of the vehicle.

16. A vehicle comprising:
a body component;
a radio antenna disposed behind the body component, the radio antenna comprising:
a folded monopole radiator,
a high impedance buffer amplifier comprising:
an input side electrically connected to the folded monopole radiator and configured to maintain a consistent level of impedance,
an output side electrically connected to a power source and configured to maintain the consistent level of impedance,
a two-pole filter configured to attenuate frequencies, and
a voltage regulator configured to supply the buffer amplifier with a fixed DC bias voltage when power is received from the power source, and
a flexible grounding cable directly wired to the amplifier and including a metallic mounting end, the flexible grounding cable positioned to assist in maintaining a consistent level of impedance at the folded monopole radiator.

17. The vehicle of claim 16, wherein the buffer amplifier and the grounding cable are configured to maintain an output impedance at 50 ohms, the output impedance received by the monopole radiator.

18. The vehicle of claim 16, wherein the monopole radiator comprises a metallic material, and wherein the monopole radiator comprises a horizontal portion and a vertical portion, the vertical portion comprising a lower end fixed to the buffer amplifier and an upper end fixed to the horizontal portion.

19. The vehicle of claim 16, wherein the monopole radiator is configured to capture signals in the FM radio band.

20. The vehicle of claim 16, wherein the metallic mounting end of the grounding cable is fixed to a metallic mounting surface of the vehicle.
